(19) United States
(12) Patent Application Publication
(10) Pub. No.: US 2026/0059954 A1
(43) Pub. Date: Feb. 26, 2026

(54) DISPLAY PANEL, ELECTRONIC DEVICE HAVING THE SAME AND METHOD OF MANUFACTURING DISPLAY PANEL

(71) Applicant: SAMSUNG DISPLAY CO., LTD., YONGIN-SI (KR)

(72) Inventors: SUNGEUN LEE, YONGIN-SI (KR); KI NYENG KANG, YONGIN-SI (KR); CHANJU PARK, YONGIN-SI (KR); HYUNHO KIM, YONGIN-SI (KR); KEUNKYU SONG, YONGIN-SI (KR)

(21) Appl. No.: 19/088,501

(22) Filed: Mar. 24, 2025

(30) Foreign Application Priority Data
Aug. 26, 2024 (KR) 10-2024-0114417

(51) Int. Cl. H10K 59/124; H10K 59/12

(52) U.S. Cl. CPC H10K 59/124; H10K 59/1201

(57) ABSTRACT

A display panel includes a base member, an active pattern, a gate insulating layer, a gate electrode, an interlayer insulating layer, a source-drain electrode, a first via planarization layer, an ashing stopper layer, a second via planarization layer, a third via planarization layer, a plurality of anode electrodes, and a plurality of light-emitting layers. The second via planarization layer is defined with a plurality of planarization opening parts. Accordingly, in the third via planarization layer provided on the second via planarization layer, portions overlapping with the plurality of planarization opening parts are concavely caved. Accordingly, the plurality of anode electrodes and the plurality of light-emitting layers also have a shape of a specific portion concavely caved according to a shape the third via planarization layer.

### CROSS-REFERENCE TO RELATED APPLICATION

The present application claims priority to and the benefit of Korean Patent Application No. 10-2024-0114417, filed on Aug. 26, 2024, in the Korean Intellectual Property Office, the entire disclosure of which is incorporated herein by reference.

### BACKGROUND

### 1. Field

One or more embodiments of the present disclosure relate to a display panel having a secured viewing angle under one or more folding angles of a device, an electronic device including the display panel, and a manufacturing method of the display panel.

### 2. Description of the Related Art

It is desirable for a display device to have a method of securing or providing a substantially constant viewing angle under one or more folding angles of a device. For example, as a foldable display device, a bendable display device, and/or a rollable display device is developed, development of such method has become more important.

A display device having one or more form factors, such as a foldable display device, a bendable display device, and/or a rollable display device, is repeatedly bent or unfolded to an angle for convenience of a user to view an image. Also, as a red pixel, a green pixel, and a blue pixel on a light-emitting layer of a display device are provided to emit light of different wavelengths, it is desirable for such display device to have a structure to emit light according to a unique wavelength range.

Applying a structure of a concave shape to a light-emitting unit of a display panel may be advantageous or beneficial for securing or providing a substantially constant viewing angle.

### SUMMARY

One or more aspects of embodiments of the present disclosure are directed toward a display panel that may secure or provide a substantially constant viewing angle under one or more folding angles of a device, an electronic device including the display panel, and a manufacturing method of a display panel (or a method of manufacturing a display panel).

One or more aspects of embodiments of the present disclosure are directed toward a display panel that meets or satisfies an optical property requirement of a customer by adjusting an angle of extension of a light-emitting unit, an electronic device including the display panel, and a manufacturing method of a display panel (or a method of manufacturing a display panel).

Additional aspects of embodiments will be set forth in part in the description which follows and, in part, will be apparent from the description or may be learned by practice of the presented embodiments of the disclosure.

A display panel according to one or more embodiments of the present disclosure includes a base member, an active pattern, a gate insulating (e.g., electrically insulating) layer, a gate electrode, an interlayer insulating (e.g., electrically insulating) layer, a source-drain electrode, a first via planarization layer, an ashing stopper layer, a second via planarization layer, a third via planarization layer, a plurality of anode electrodes, and a plurality of light-emitting layers. The active pattern may include a semiconductor material and be on the base member. The gate insulating (e.g., electrically insulating) layer may cover the active pattern. The gate electrode may be on the gate insulating (e.g., electrically insulating) layer and have at least a portion that overlaps with the active pattern. The interlayer insulating (e.g., electrically insulating) layer may be on the gate electrode. The source-drain electrode may be on the interlayer insulating (e.g., electrically insulating) layer. The first via planarization layer may be on the source-drain electrode. The ashing stopper layer may include an inorganic material and be on the first via planarization layer. The second via planarization layer may be on the ashing stopper layer and define a plurality of planarization opening parts. The third via planarization layer may be on the second via planarization layer. The plurality of anode electrodes may be on the third via planarization layer and have at least one overlapping with the plurality of planarization opening parts. Each of the plurality of light-emitting layers may be on the plurality of anode electrodes.

In one or more embodiments of the present disclosure, the plurality of light-emitting layers may include a first light-emitting layer that overlaps with one of the plurality of planarization opening parts. The first light-emitting layer may include a first light-emitting unit that extends in a selectable direction and a second light-emitting unit that extends in a direction that crosses (e.g., intersects) with the selectable direction.

In one or more embodiments of the present disclosure, an angle between a plane parallel (e.g., substantially parallel) to the first via planarization layer and the second light-emitting unit may be about 15 degrees or more and about 25 degrees or less.

In one or more embodiments of the present disclosure, a distance between an upper surface of the first via planarization layer and the first light-emitting unit may be less than a distance between the upper surface of the first via planarization layer and the second light-emitting unit.

In one or more embodiments of the present disclosure, a distance between a portion of the upper surface of the third via planarization layer that overlaps with the planarization opening part and the upper surface of the first via planarization layer may be a first distance. A distance between a portion of the upper surface of the third via planarization layer that does not overlap with the planarization opening part and the upper surface of the first planarization layer may be a second distance. The first distance may be less than the second distance.

In one or more embodiments of the present disclosure, at least one of the plurality of anode electrodes may include a first anode unit that extends in the selectable direction and a second anode unit that extends in a direction that crosses (e.g., intersects) with the selectable direction.

In one or more embodiments of the present disclosure, the plurality of light-emitting layers may further include a second light-emitting layer. A distance between the upper surface of the first planarization layer and a bottom surface of the first light-emitting layer may be less than a distance between the upper surface of the first via planarization layer and a bottom surface of the second light-emitting layer.

In one or more embodiments of the present disclosure, the first light-emitting layer may be provided to emit light having a first wavelength, and the second light-emitting layer may be provided to emit light having a second wavelength that is shorter than the first wavelength.

In one or more embodiments of the present disclosure, a hard mask layer may include a metal material. The hard mask layer may be defined with a plurality of metal opening parts that overlap with the plurality of planarization opening parts. The hard mask layer may be between the second via planarization layer and the third via planarization layer.

In one or more embodiments of the present disclosure, an angle between each of inner surfaces that defines the plurality of planarization opening parts and a normal line of the ashing stopper layer may be an acute angle.

The electronic device according to one or more embodiments of the present disclosure may include a display panel. The display panel may include a base member, an active pattern, a gate insulating (e.g., electrically insulating) layer, a gate electrode, an interlayer insulating (e.g., electrically insulating) layer, a source-drain electrode, a first via planarization layer, an ashing stopper layer, a second via planarization layer, a third via planarization layer, a plurality of anode electrodes, and a plurality of light-emitting layers. The active pattern may include a semiconductor material and be on the base member. The gate insulating (e.g., electrically insulating) layer may cover the active pattern. The gate electrode may be on the gate insulating (e.g., electrically insulating) layer and be disposed to have at least a portion that overlaps with the active pattern. The interlayer insulating (e.g., electrically insulating) layer may be on the gate electrode. The source-drain electrode may be on the interlayer insulating (e.g., electrically insulating) layer. The first via planarization layer may be on the source-drain electrode. The ashing stopper layer may include an inorganic material and be on the first via planarization layer. The second via planarization layer may be on the ashing stopper layer and define a plurality of planarization opening parts. The third via planarization layer may be on the second planarization layer. The plurality of anode electrodes may be on the third via planarization layer and have at least one overlapping with the plurality of planarization opening parts. Each of the plurality of light-emitting layers may be on the plurality of anode electrodes.

In one or more embodiments of the present disclosure, the plurality of light-emitting layers may include a first light-emitting layer overlapping with any one of the plurality of planarization opening parts. The first light-emitting layer may include a first light-emitting unit that extends in a selectable direction and a second light-emitting unit that extends in a direction that crosses (e.g., intersects) with the selectable direction.

In one or more embodiments of the present disclosure, an angle between a plane parallel (e.g., substantially parallel) to the first via planarization layer and the second light-emitting unit may be about 15 degrees or more and about 25 degrees or less.

In one or more embodiments of the present disclosure, a distance between an upper surface the first via planarization layer and the first light-emitting unit may be less than a distance between the upper surface of the first via planarization layer and the second light-emitting unit.

In one or more embodiments of the present disclosure, a distance between a portion of an upper surface of the third via planarization layer that overlaps with the planarization opening part and the upper surface of the first via planarization layer may be a first distance. A distance between a portion of the upper surface of the third via planarization layer that does not overlap with the planarization opening part and the upper surface of the first planarization layer may be a second distance. The first distance may be less than the second distance.

In one or more embodiments of the present disclosure, the at least one of the plurality of anode electrodes may include a first anode unit that extends in the selectable direction and a second anode unit that extends in a direction that crosses (e.g., intersects) with the selectable direction.

In one or more embodiments of the present disclosure, the plurality of light-emitting layers may include a second light-emitting layer. A distance between an upper surface of the first via planarization layer and a bottom surface of the first light-emitting layer may be less than a distance between the upper surface of the first via planarization layer and a bottom surface of the second light-emitting layer.

In one or more embodiments of the present disclosure, the first light-emitting layer may be provided to emit light having a first wavelength, and the second light-emitting layer may be provided to emit light having a second wavelength shorter than the first wavelength.

A method of manufacturing a display panel according to one or more embodiments of the present disclosure includes a step of providing a first via planarization layer, a step of providing an ashing stopper layer, a step of providing a second via planarization layer, a step of providing a hard mask layer, a step of providing a metal opening part, a step of providing a planarization opening part, a step of providing a third via planarization layer, a step of providing an anode electrode, and a step of providing a light-emitting layer. In the step of providing a first via planarization layer, a first via planarization layer that covers an electrode pattern may be provided. After the step of providing a first via planarization layer, a step of providing an ashing stopper layer to provide an ashing stopper layer including an inorganic material on the first via planarization layer may be included. After the step of providing the ashing stopper layer, a step of providing a second via planarization layer to provide the second via planarization layer on the ashing stopper layer may be included. After the step of providing the second via planarization layer, a step of providing a hard mask to provide a hard mask layer including a metallic material on the second via planarization layer may be included. After the step of providing the hard mask layer, a step of providing a metallic opening part to provide a metallic opening part on the hard mask layer may be included. After the step of providing the metallic opening part, a step of providing a planarization opening part to provide a planarization opening part that overlaps with the metallic opening part on the second via planarization layer may be included. After the step of providing the planarization opening part, a step of providing a third via planarization layer to provide a third via planarization layer on the second via planarization layer may be included. After the step of providing the third via planarization layer, a step of providing an anode electrode to provide an anode electrode on the third via planarization layer to overlap with the planarization opening part may be included. After the step of providing the anode electrode, a step of providing a light-emitting layer to provide a light-emitting layer on the anode electrode may be included.

One or more embodiments of the present disclosure provide a display panel having a secured viewing angle under one or more folding angles of a device, an electronic device including the display panel, and a method of manufacturing a display panel.

One or more embodiments of the present disclosure provide a display panel that meets or satisfies an optical property requirement of a customer by adjusting an angle of extension of a light-emitting unit, an electronic device including the display panel, and a method of manufacturing a display panel.

### BRIEF DESCRIPTION OF THE DRAWINGS

The above and other aspects and features of certain embodiments of the present disclosure will become more apparent and more readily appreciated from the following description of one or more embodiments, taken in conjunction with the accompanying drawings in which:

FIGS. 1A and 1B are schematic views of an electronic device according to one or more embodiments of the present disclosure;

each of FIGS. 2A-2D is a cross-sectional view of an electronic device according to one or more embodiments of the present disclosure;

FIG. 3 is an exemplary illustration of a portion of a cross-section of a display panel according to one or more embodiments of the present disclosure;

FIG. 4 is an exemplary magnified view of a region marked with AA as illustrated in FIG. 3;

FIG. 5 is an exemplary magnified view of a region marked with AA as illustrated in FIG. 3 according to one or more embodiments of the present disclosure;

FIG. 6 is an exemplary illustration of a portion of a cross-section of a display panel according to one or more embodiments of the present disclosure;

FIG. 7 is an exemplary illustration of a portion of a cross-section of a display panel according to one or more embodiments of the present disclosure;

FIG. 8 is an exemplary illustration of a portion of a cross-section of a display panel according to one or more embodiments of the present disclosure;

FIG. 9 is an exemplary illustration of a portion of a cross-section of a display panel according to one or more embodiments of the present disclosure;

FIG. 10 is flow chart of a manufacturing method of a display panel according to one or more embodiments of the present disclosure;

FIG. 11A is an exemplary illustration of a layout of the first via planarization layer as illustrated in FIG. 4;

FIG. 11B is an illustration of the addition of an ashing stopper layer to FIG. 11A;

FIG. 11C is an illustration of the addition of a second via planarization layer to FIG. 11B;

FIG. 11D is an illustration of the addition of a hard mask layer to FIG. 11C;

FIG. 11E is an exemplary illustration of a step of providing a first metallic opening part in FIG. 11D;

FIG. 11F is an exemplary illustration of a step of providing a first planarization opening part in FIG. 11E;

FIG. 11G is an illustration of the addition of a layout of a third via planarization layer to FIG. 11f;

FIG. 11H is an illustration of the addition of a layout of a first anode electrode to FIG. 11G;

FIG. 11I is an illustration of the addition of a layout of a hole functional layer to FIG. 11H; and

FIG. 11J is an illustration of the addition of a layout of a first light-emitting layer to FIG. 11I.

FIG. 12 is an exemplary block diagram of an electronic device according to one or more embodiments.

FIG. 13 illustrates schematic diagrams of electronic devices according to one or more embodiments.

### DETAILED DESCRIPTION

References will be made in more detail to one or more embodiments, of which examples are illustrated in the accompanying drawings, where like reference numerals refer to like elements throughout. In this regard, the subject matter of the present disclosure may be embodied in different forms and permutations, but the present disclosure shall by no means be construed as being limited to one or more embodiments set forth herein. Rather, the present disclosure shall be construed to encompass all forms, permutations, equivalents, and substitutes covered by the spirit and scope of the present disclosure. Rather, these embodiments are provided as examples, by referring to the figures, to explain the aspects and features of the present disclosure to those skilled in the art.

Like or identical reference numerals refer to like or identical elements. Moreover, in the accompanying drawings, the thicknesses, ratios, and dimensions of the elements may not be to exact scale and may have been exaggerated to effectively or suitably illustrate the technical features of the present disclosure associated with these elements. As such, the present disclosure shall not be restricted to the thicknesses, ratios, dimensions, and/or the like as illustrated in the drawings.

An expression, such as “has/have,” “having,” “include/includes,” or “including,” is intended to designate a characteristic, a number, a step, an operation, an element, a part, or combinations thereof, and shall not be construed to preclude any possibility of presence or addition of one or more other characteristics, numbers, steps, operations, elements, parts, or combinations thereof.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise defined, all terms, including technical terms and scientific terms, used herein have substantially the same meaning as how they are generally understood by those of ordinary skill in the art to which the present disclosure pertains. Any term that is defined in a dictionary, that is generally available or generally used, shall be construed to have substantially the same meaning in the context of the relevant art, and, unless otherwise defined explicitly, shall not be interpreted to have an idealistic or excessively formalistic meaning.

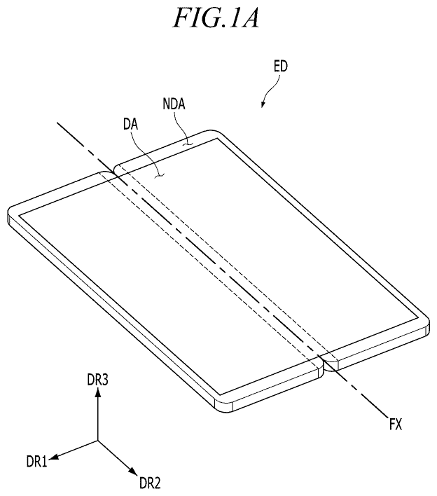

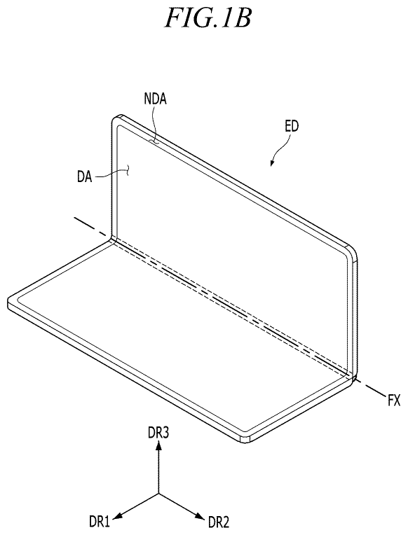

FIGS. 1A and 1B are schematic views of an electronic device ED according to one or more embodiments of the present disclosure.

According to one or more embodiments of the present disclosure, FIG. 1 exemplarily illustrates a display device as an electronic device ED. For example, a foldable display device, that is foldable along a folding axis FX, is exemplarily illustrated as the electronic device ED. However, embodiments of the present disclosure are not limited to what is illustrated in the figure, and one or more suitable electronic devices may be included. For example, the display device may be a device to display an image in front, such as, a monitor, a television, a smartphone, a wearable device, a navigation, and/or a tablet. A shape and/or a function are not limited thereto. For example, a front face may be one or more suitable shapes, such as, a circle (e.g., a substantially circular shape) or a polygon (e.g., a substantially polygonal shape). In one or more embodiments, the display device may be a bendable display device and/or a rollable display device.

A first direction DR1, a second direction DR2, and a third direction DR3 may be defined. The first direction DR1 and the second direction DR2 may be directions defined on a plane of the electronic device ED as illustrated in FIG. 1 and may cross (e.g., intersect) with each other. The third direction DR3 may be a thickness direction of the electronic device ED as illustrated in FIG. 1.

FIGS. 2A, 2B, 2C, and 2D are cross-sectional views of an electronic device ED according to one or more embodiments of the present disclosure. According to one or more embodiments of the present disclosure, a display device is exemplarily illustrated as an electronic device ED. FIGS. 2A, 2B, 2C, and 2D are simplified to describe laminated relations among the functional panels and/or the functional members that compose the display device.

As illustrated in FIG. 2A, the electronic device ED may include a display panel DP, an input sensor circuit ISC, a reflection protection member RPP, and a window member WP. The input sensor circuit ISC may be directly on the display panel DP. If (e.g., when) an element is “directly disposed on” or “directly on” another element, it shall be construed that there is no other adhesive layer/adhesive member therebetween.

In the present disclosure, a display module DPM may be defined to include the display panel DP and the input sensor circuit ISC on the display panel DP. An optically clear (e.g., substantially clear) adhesive member OCA may be provided each of between the display module DPM and the reflection protection member RPP and between the reflection protection member RPP and the window member WP.

The display panel DP may reproduce an image, and the input sensor circuit ISC may obtain a coordination information of the external input (e.g., microcurrent and/or applied pressure). The display module DPM according to one or more embodiments of the present disclosure may further include a protective plate below the display panel DP. The protective plate and the display panel DP may be coupled by an adhesive member. The display devices of FIGS. 2B, 2C, and 2D as described hereinafter may also further include a protective member.

The display panel DP according to one or more embodiments of the present disclosure may be a light-emitting display panel. For example, a display panel DP may be an organic light-emitting display panel, a quantum dot light-emitting display panel, or a micro light-emitting display panel. A light-emitting layer of an organic light-emitting display panel may include an organic light-emitting material. An inorganic light-emitting display panel of an inorganic material may include a quantum dot light-emitting display panel or a micro light-emitting display panel. Hereinafter, the display panel DP is described in more detail as an organic light-emitting display panel.

The display panel DP may be defined with a display region DA and a non-display region NDA. The display region DA may be a region to display an image, and the non-display region NDA may be a region adjacent to the display region DA and a region where an image is not displayed. The non-display region NDA may be around (e.g., surround) the display region DA. However, this is an exemplary illustration, and the non-display region NDA may be adjacent to a portion of an edge of the display region DA and not limited to the disclosed embodiments.

The reflection protection plate RPP may reduce a reflection rate of an external light incident from an upper side of the window plate WP. The reflection protection plate RPP according to one or more embodiments of the present disclosure may include a retarder and a polarizer.

The reflection protection plate RPP according to one or more embodiments of the present disclosure may include color-filters.

The window plate WP according to one or more embodiments of the present disclosure may include a base film WP-BS and a light-blocking pattern WP-BZ. The base film WP-BS may include glass and/or a synthetic resin. The base film WP-BS is not limited to a single layer. The base film WP-BS may include two or more films coupled by an adhesive member.

The light-blocking pattern WP-BZ may partially overlap with the base film WP-BS. The light-blocking pattern WP-BZ may be below the base film WP-BS to define the bezel area, e.g., the non-display area NDA, of the display device

Hereinafter, the light blocking pattern WP-BZ and the base film WP-BS may not be illustrated in FIGS. 2B, 2C, and 2D.

As illustrated in FIG. 2B, the electronic device ED may include a display panel DP, a reflection protection plate RPP, an input sensor circuit ISC, and a window plate WP.

The display panel DP and the reflection protection plate RPP may be coupled by an optically clear adhesive member OCA. The reflection protection plate RPP and the input sensor circuit ISC may be coupled by an optically clear adhesive member OCA. The input sensor circuit ISC and the window plate WP may be coupled by an optically clear adhesive member OCA.

Referring to FIG. 2C, a difference from FIG. 2B is that the positions of the reflection protection plate RPP and the input sensor circuit ISC may be switched.

As illustrated in FIG. 2D, the adhesive members may not be provided in the electronic device ED, and the display panel DP, the input sensor circuit ISC, the reflection protection plate RPP, and the window plate WP may be sequentially laminated. In one or more embodiments of the present disclosure, the lamination order of the input sensor circuit ISC and the reflection protection plate RPP may be switched.

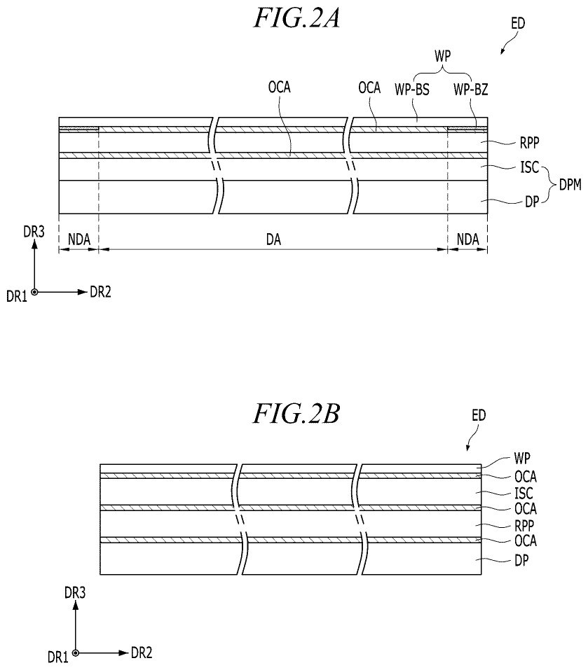

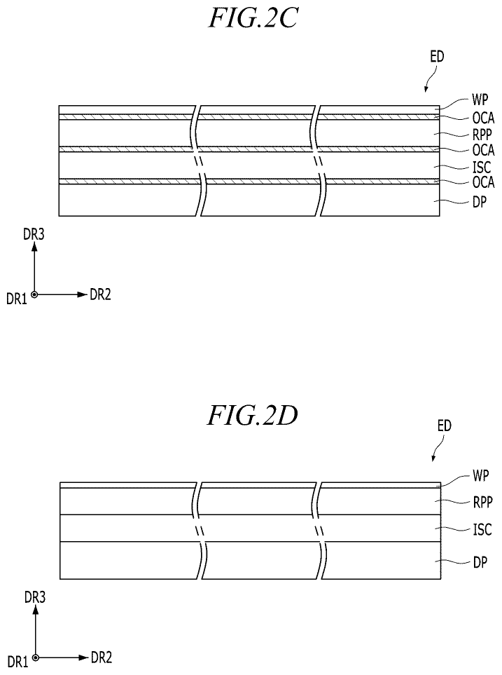

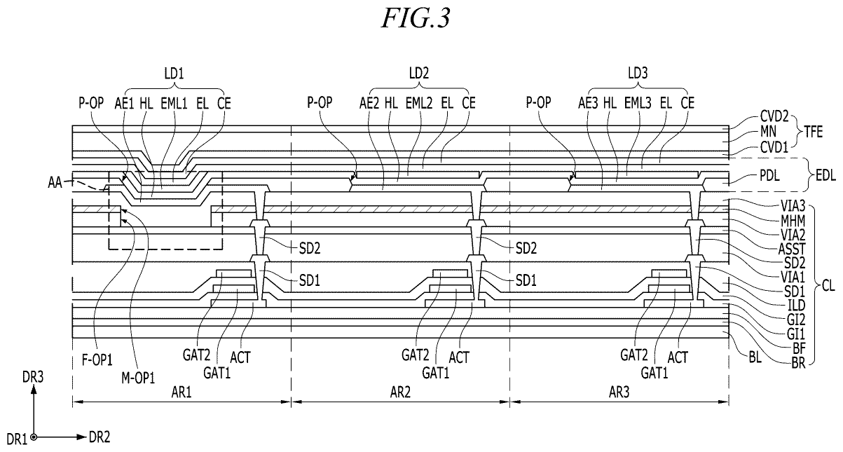

FIG. 3 is an exemplary illustration of a portion of a cross-section of a display panel DP according to one or more embodiments of the present disclosure.

The display panel DP may include a base member BL, a circuit layer CL, a light-emitting diode layer EDL, and an encapsulation layer TFE.

The base member BL may include at least one selected from an organic material and an inorganic material, such as glass.

The circuit layer CL may be on the base member BL. The circuit layer CL may include a barrier layer BR, a buffer layer BF, an active pattern ACT, gate insulating layers GI1 and GI2, gate electrodes GAT1 and GAT2, an interlayer insulating layer ILD, source-drain electrodes SD1 and SD2, via planarization layers VIA1, VIA2 and VIA3, an ashing stopper layer ASST, and a hard mask layer MHM. In one or more embodiments, the circuit layer CL may include a transistor. A portion of the active pattern ACT may compose an active unit of the transistor, a portion of the gate electrodes GAT1 and GAT2 may compose a control electrode of the transistor, and a portion of the source-drain electrodes SD1 and SD2 may compose an input electrode and an output electrode of the transistor.

The light-emitting diode layer EDL may be on the circuit layer CL. The light-emitting diode layer EDL may include light-emitting diodes LD1, LD2, and LD3 and a pixel defining film PDL.

The encapsulation layer TFE may be provided to seal off the light-emitting diode layer EDL to protect the light-emitting diode layer EDL from external oxygen and/or moisture (or reduce a degree to or occurrence of which the light-emitting diode layer EDL is exposed to external oxygen and/or moisture).

The encapsulation layer TFE may include a first inorganic layer CVD1, an organic layer MN, and a second inorganic layer CVD2. In FIG. 3, the encapsulation layer TFE is illustrated, as an example, to include two inorganic layers and one organic layer, but embodiments of the present disclosure are not limited to this example. For example, the encapsulation layer TFE may include three inorganic layers and two organic layers, and, in one or more embodiments, the inorganic layers and the organic layers may be alternately laminated.

A functional layer, such as a barrier layer BR and/or a buffer layer BF, may be on one side of the base member BL. The functional layer may include a barrier layer BR and/or a buffer layer BF.

The functional layer, such as a barrier layer BR and/or a buffer layer BF, may be provided to prevent an impurity that exists at the bottom from flowing into a pixel during a manufacturing process (or to reduce a degree to or occurrence of which an impurity that exists at the bottom flows into a pixel during a manufacturing process). For example, the functional layer, such as a barrier layer BR and/or a buffer layer BF, may be provided to prevent the spread of an impurity to the active pattern ACT that composes a pixel (or to reduce a degree to or occurrence of which an impurity spreads to the active pattern ACT that composes a pixel.

The active pattern ACT that composes a transistor may be on the buffer layer BF. The active pattern ACT may include polysilicon and/or amorphous (e.g., non-crystalline) silicon. In one or more embodiments, the active pattern ACT may include a polycrystalline silicon, a monocrystalline silicon, a low temperature polycrystalline silicon, and/or a metallic oxide semiconductor.

The active pattern ACT may include a channel area that serves as a passage through which an electron or a hole may move, and a first ion-doped area and a second ion-doped area having the channel area therebetween.

A first gate insulating layer GI1 that covers the active pattern ACT may be on the buffer layer BF. The first gate insulating layer GI1 may include an inorganic film, such as a silicon nitride layer, a silicon oxynitride layer, a silicon oxide layer, and/or an aluminum oxide layer. However, embodiments of the present disclosure are not limited to thereto.

A first gate electrode GAT1 may be on the first gate insulating layer GI1. The first gate electrode GAT1 may be of a single layer or multiple layers of one of molybdenum (Mo), aluminum (Al), chromium (Cr), gold (Au), titanium (Ti), nickel (Ni), neodymium (Nd), copper (Cu), or an alloy thereof.

A second gate insulating layer GI2 that covers the first gate electrode GAT1 may be on the first gate insulating layer GI1. The second gate insulating layer GI2 may include an inorganic film, such as a silicon nitride layer, a silicon oxynitride layer, a silicon oxide layer, and/or an aluminum oxide layer. However, embodiments of the present disclosure are not limited to thereto.

A second gate electrode GAT2 may be on the second gate insulating layer GI2.

The second gate electrode GAT2 may be of a single layer or multiple layers of one of molybdenum (Mo), aluminum (Al), chromium (Cr), gold (Au), titanium (Ti), nickel (Ni), neodymium (Nd), copper (Cu), or an alloy thereof.

FIG. 3 exemplarily illustrates that gate electrodes GAT1 and GAT2 of the transistor may be on the active pattern ACT as a shape of an upper gate, but embodiments of the present disclosure are not limited thereto. The gate electrodes GAT1 and GAT2 of the transistor may be below the active pattern ACT as a shape of a bottom gate, or the gate electrodes GAT1 and GAT2 may be on and below the active pattern ACT as a shape of a double gate.

The interlayer insulating layer ILD that covers the second gate electrode GAT2 may be on the second gate insulating layer GI2. The interlayer insulating layer ILD may include an organic film and/or an inorganic film. The interlayer insulating layer ILD may include a plurality of inorganic thin films and/or a plurality of organic thin films. The plurality of inorganic thin films may include a nitride layer and/or a silicon oxide layer.

The first source-drain electrode SD1 may be on the interlayer insulating layer ILD. The first source-drain electrode SD1 may be connected to the active pattern ACT through a contact hole that penetrates the gate insulating layers GI1 and GI2 and the interlayer insulating layer ILD.

The first via planarization layer VIA1 may be on the first source-drain electrode SD1. The first via planarization layer VIA1 may include an organic film and/or an inorganic film. For example, an organic film of an acryl resin, an epoxy resin, a phenol resin, and/or a polyimide resin may be included. The first via planarization layer VIA1 may provide a flat surface (e.g., a substantially flat surface).

The ashing stopper layer ASST may be on the first via planarization layer VIA1. The ashing stopper layer ASST may include an inorganic material. The ashing stopper layer ASST may be provided to prevent the first via planarization layer VIA1 from being etched during performing an ashing process (or to reduce a degree to or occurrence of which the first via planarization layer VIA1 is etched during performing an ashing process). In one or more embodiments, the upper thickness and the lower thickness of the second via planarization layer VIA2 on the ashing stopper layer ASST may be adjusted to a desired width.

The second source-drain electrode SD2 may be on the ashing stopper layer ASST. The second source-drain electrode SD2 may be connected to the first source-drain electrode SD1 through a contact hole that penetrates the ashing stopper layer ASST and the first via planarization layer VIA1.

The second via planarization layer VIA2 may be on the second source-drain electrode SD2. The second via planarization layer VIA2 may include an organic film and/or an inorganic film. For example, an organic film of an acryl resin, an epoxy resin, a phenol resin, and/or a polyimide resin may be included. The second via planarization layer VIA2 may provide a flat surface (e.g., a substantially flat surface).

According to one or more embodiments of the present disclosure, the second planarization layer VIA2 may be defined with a first planarization opening part F-OP1. In one or more embodiments, the second via planarization layer VIA2 may be more defined with a plurality of planarization opening parts other than the first planarization opening part F-OP1.

The hard mask layer MHM may be on the second via planarization layer VIA2. The hard mask layer MHM may include a metallic material. The hard mask layer MHM may be provided to prevent a portion of the second via planarization layer VIA2 from being etched during performing a photoresist process (or to reduce a degree to or occurrence of which a portion of the second via planarization layer VIA2 is etched during performing a photoresist process). In one or more embodiments, a width from left to right of the first planarization opening part F-OP1 defined on the second via planarization layer VIA2 may be adjusted to a desired width.

According to one or more embodiments of the present disclosure, the hard mask layer MHM may be defined with a first metallic opening part M-OP1. In one or more embodiments, the hard mask layer MHM may be more defined with a plurality of metallic opening parts other than the first metallic opening part M-OP1.

According to one or more embodiments of the present disclosure, the first metallic opening part M-OP1 may overlap with the first planarization opening part F-OP1.

The third via planarization layer VIA3 may be on the hard mask layer MHM. The third via planarization layer VIA3 may include an organic film and/or an inorganic film. For example, an organic film of an acryl resin, an epoxy resin, a phenol resin, and/or a polyimide resin may be included. The third via planarization layer VIA3 may provide a flat surface (e.g., a substantially flat surface). The third via planarization layer VIA3 may be between the anode electrodes AE1, AE2, and AE3 and the hard mask layer MHM.

A pixel defining film PDL and/or light-emitting diodes LD1, LD2, and LD3 may be on the third via planarization layer VIA3.

The first light-emitting diode LD1 may include a first anode electrode AE1, a hole functional layer HL, a first light-emitting layer EML1, an electron functional layer EL, and a cathode electrode CE.

The second light-emitting diode LD2 may include a second anode electrode AE2, a hole functional layer HL, a second light-emitting layer EML2, an electron functional layer EL, and a cathode electrode CE.

The third light-emitting diode LD3 may include a third anode electrode AE3, a hole functional layer HL, a third light-emitting layer EML3, an electron functional layer EL, and a cathode electrode CE.

The anode electrodes AE1, AE2, and AE3 may be connected to the second source-drain electrode SD2 through a contact hole that penetrates the third via planarization layer VIA3 and the second via planarization layer VIA2. The anode electrodes AE1, AE2, and AE3 may overlap with the first metallic opening part M-OP1 and the first planarization opening part F-OP1.

A pixel opening part P-OP defined on the pixel defining film PDL may expose the anode electrodes AE1, AE2, and AE3.

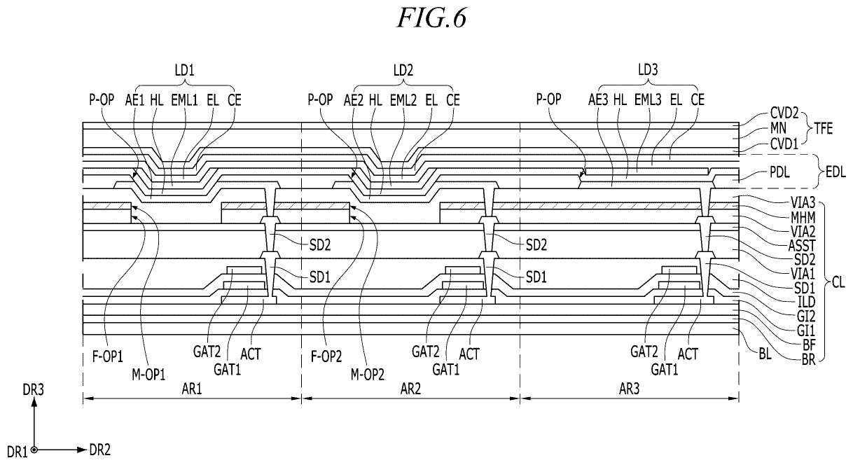

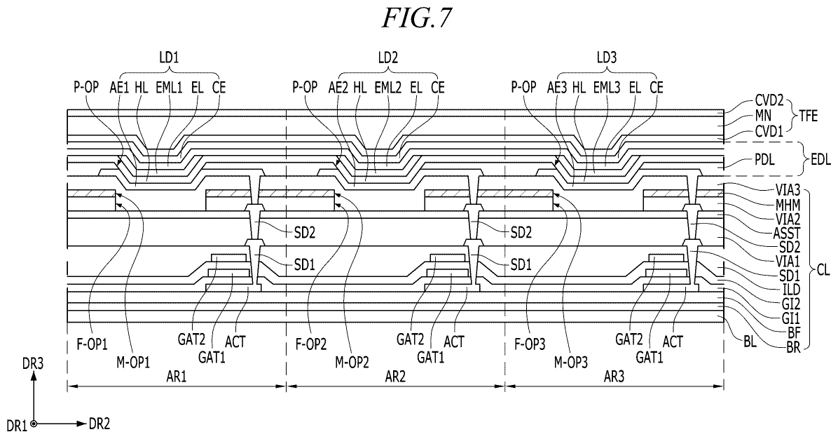

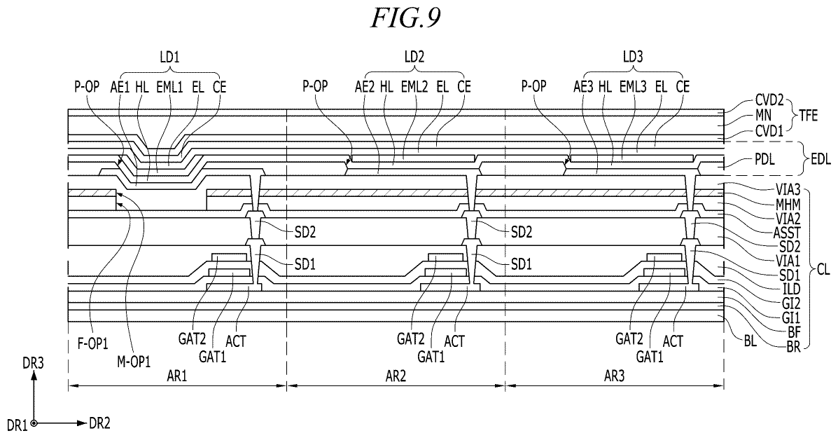

In the present disclosure, the first light-emitting diode LD1, the second light-emitting diode LD2, and the third light-emitting diode LD3 are illustrated as being in parallel (e.g., substantially parallel). However, it should be understood that the first light-emitting diode LD1, the second light-emitting diode LD2, and the third light-emitting diode LD3 may not be on substantially the same plane and may not be electrically connected. This is substantially the same as in FIG. 6, FIG. 7, and FIG. 9.

According to one or more embodiments of the present disclosure, FIG. 3 may be divided into a first region AR1, a second region AR2, and a third region AR3. Hereinafter, FIGS. 6, 7, 8 and 9 may also be divided into the first region AR1, the second region AR2, and the third region AR3.

According to one or more embodiments of the present disclosure, the first region AR1 in FIG. 3 may be applied by a concave structure (e.g., a substantially concave structure) to provide the first light-emitting layer EML1 in a concave shape (e.g., in a substantially concave shape). The second region AR2 may be applied by a non-concave structure to provide the second light-emitting layer EML2 in a flat shape (e.g., a substantially flat shape). The third region AR3 may be applied by a non-concave structure to provide the third light-emitting layer EML3 in a flat shape (e.g., a substantially flat shape).

According to one or more embodiments of the present disclosure, a distance between an upper surface of the first via planarization layer VIA1 and a bottom surface of the first light-emitting layer EML1 may be less than a distance between the upper surface of the first via planarization layer VIA1 and a bottom surface of the second light-emitting layer EML2.

The first light-emitting layer EML1, the second light-emitting layer EML2, and the third light-emitting layer EML3 may be provided to emit light having different wavelengths. A wavelength of light emitted from the first light-emitting layer EML1 may be shorter than a wavelength of light emitted from the second light-emitting layer EM2, and the wavelength of light emitted from the second light-emitting layer EML2 may be even shorter than the wavelength of light emitted from the third light-emitting layer EML3. As an example, the first light-emitting layer EML1 may emit red light, the second light-emitting layer EML2 may emit green light, and the third light-emitting layer EML3 may emit blue light.

According to one or more embodiments of the present disclosure, if (e.g., when) the first light-emitting layer EML1 that emits red light is applied with a concave structure (e.g., a substantially concave structure), it may be effective or suitable to secure or provide a substantially constant viewing angle to view under one or more folding angles of a device and reduce a phenomenon of a screen shown blue. However, embodiments of the present disclosure are not limited thereto, and a wavelength of light emitted each from the first light-emitting layer EML1, the second light-emitting layer EML2, and the third light-emitting layer EML3 may be modified. According to one or more embodiments of the present disclosure, the first light-emitting layer EML1 may overlap with the first metallic opening part M-OP1 and the first planarization opening part F-OP1.

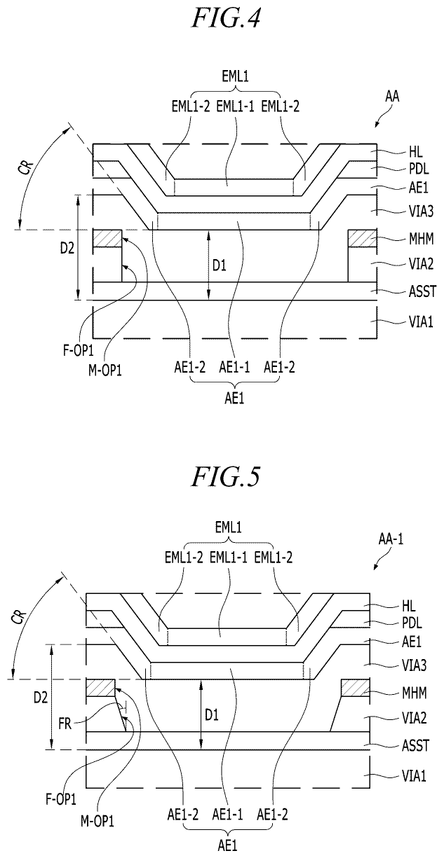

Hereinafter, a concave structure (e.g., a substantially concave structure) to provide the first light-emitting layer EML1 in a concave shape (e.g., in a substantially concave shape) is explained with reference to FIG. 4 in more details.

FIG. 4 is an exemplary magnified view of a portion marked with AA in FIG. 3.

The third via planarization layer VIA3 may have a concave structure (e.g., a substantially concave structure) by the first planarization opening part F-OP1 and the first metallic opening part M-OP1. For example, a distance between a portion of the upper surface of the third via planarization layer VIA3 that overlaps with the first flat-opening part F-OP1 and the first metallic opening part M-OP1 and the upper surface of the first via planarization layer VIA1 may be a first distance D1. A distance between a portion of the upper surface of the third via planarization layer VIA3 that does not overlap with the first planarization opening part F-OP1 and the first metallic opening part M-OP1 and the upper surface of the first via planarization layer VIA1 may be a second distance D2. In one or more embodiments, the first distance D1 may be less than the second distance D2.

According to one or more embodiments of the present disclosure, the first light-emitting layer EML1 may include a first light-emitting unit EML1-1 that extends in a selectable direction and a second light-emitting unit EML1-2 that extends in a direction that crosses (e.g., intersects) with the selectable direction.

According to one or more embodiments of the present disclosure, an angle CR between a plane parallel (e.g., substantially parallel) to the first via planarization layer VIA1 and the second light-emitting unit EML1-2 may be about 15 degrees or more and about 25 degrees or less.

If (e.g., when) the first light-emitting layer EML1 is an organic light-emitting layer, a substantial decrease in luminance may occur at a viewing angle of about 20 degrees or higher depending on a property of a material. In one or more embodiments, in consideration of process dispersion, a decrease in luminance may be prevented if (e.g., when) the angle CR between the plane parallel (e.g., substantially parallel) to the first via planarization layer VIA1 and the second light-emitting unit EML1-2 is about 15 degrees or more and about 25 degrees or less. However, this is a suggested angle as an example, and the angle may be modified according to one or more embodiments as desired or required.

According to one or more embodiments of the present disclosure, a distance between the upper surface of the first via planarization layer VIA1 and the first light-emitting unit EML1-1 may be less than a distance between the upper surface of the first via planarization layer VIA1 and the second light-emitting unit EML1-2.

According to one or more embodiments of the present disclosure, the first anode electrode AE1 may include a first anode unit AE1-1 that extends in a selectable direction and a second anode unit AE1-2 that extends in a direction that crosses (e.g., intersects) with the selectable direction.

According to one or more embodiments of the present disclosure, an angle between a plane parallel (e.g., substantially parallel) to the first via planarization layer VIA1 and the second anode unit AE1-2 may be about 15 degrees or more and about 25 degrees or less. However, this is a suggested angle as an example, and the angle may be modified according to one or more embodiments as desired or required.

In one or more embodiments of the present disclosure, a plane that defines the first planarization opening part F-OP1 of the second via planarization layer VIA2 may be orthogonal (e.g., substantially orthogonal) to the ashing stopper layer ASST.

FIG. 5 is another exemplary magnified view of a section marked with AA as illustrated in FIG. 3. A difference from FIG. 4 is that a plane that defines the planarization opening part F-OP1 of the second via planarization layer VIA2 may not be orthogonal to the ashing stopper layer ASST in FIG. 5.

For example, an angle between a normal (e.g., substantially perpendicular) direction of the ashing stopper layer ASST and an inner plane surface that defines the first planarization opening part F-OP1 of the second planarization layer VIA2 may be an acute angle. Hereinafter, a more detailed description of another element may be substantially the same as in FIGS. 3 and 4, and therefore may not be provided.

FIG. 6 is an exemplary illustration of a portion of a cross-section of a display panel DP according to one or more embodiments of the present disclosure. A difference from FIG. 3 is that a concave structure (e.g., a substantially concave structure) to provide the light-emitting layers EML1 and EML2 in a concave shape (e.g., in a substantially concave shape) on the first region AR1 and the second region AR2 may be applied in FIG. 6. The third region AR3 may be applied with a non-concave structure to provide the third light-emitting layer EML3 in a flat shape (e.g., a substantially flat shape).

Furthermore, a second planarization opening part F-OP2 may be defined on the second via planarization layer VIA2 in the second region AR2 as illustrated in FIG. 6. In one or more embodiments, a second metallic opening part M-OP2 may be defined on the hard mask layer MHM in the second region AR2 as illustrated in FIG. 6.

According to one or more embodiments of the present disclosure, the second metallic opening part M-OP2 may overlap with the second planarization opening part F-OP2.

According to one or more embodiments of the present disclosure, the second light-emitting layer EML2 may overlap with the second metallic opening part M-OP2 and the second planarization opening part F-OP2.

According to one or more embodiments of the present disclosure, the second anode electrode AE2 may overlap with the second metallic opening part M-OP2 and the second planarization opening part F-OP2.

Hereinafter, a description of a concave structure (e.g., a substantially concave structure) may be substantially the same as in FIGS. 3 and 4, and therefore may not be provided.

FIG. 7 is an exemplarily illustration of a cross-section of a display panel DP according to one or more embodiments of the present disclosure. A difference from FIG. 6 is that a concave structure (e.g., a substantially concave structure) to provide the light-emitting layers EML1, EML2 and EML3 in a concave shape (e.g., in a substantially concave shape) may be applied to the first region AR1, the second region AR2, and the third region AR3.

In FIG. 7, the third region AR3 may be defined with a third planarization opening part F-OP3 on the second via planarization layer VIA2. In one or more embodiments, in FIG. 7, the third region AR3 may be defined with a third metallic opening part M-OP3 on the hard mask layer MHM.

According to one or more embodiments of the present disclosure, the third metallic opening part M-OP3 may overlap with the third planarization opening part F-OP3.

According to one or more embodiments of the present disclosure, the third emitting layer EML3 may overlap with the third metallic opening part M-OP3 and the third planarization opening part F-OP3.

According to one or more embodiments of the present disclosure, the third anode electrode AE3 may overlap with the third metallic opening part M-OP3 and the third planarization opening part F-OP3.

Hereinafter, a description of a concave structure (e.g., a substantially concave structure) may be substantially the same as in FIGS. 3 and 4, and therefore may not be provided.

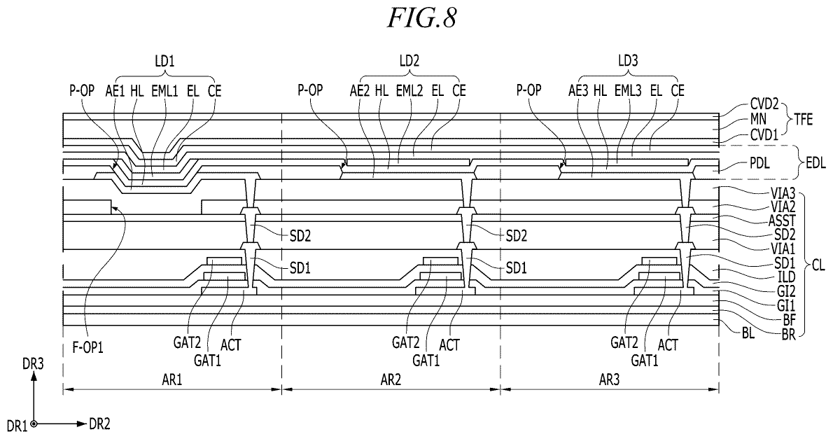

FIG. 8 is an exemplary illustration of a portion of a cross-section of a display panel DP according to one or more embodiments of the present disclosure. A difference from the lamination structure as illustrated in FIG. 3 is that a lamination structure having a removed hard mask layer MHM on the second planarization layer VIA2 is illustrated in FIG. 8. Hereinafter, a description of a concave structure (e.g., a substantially concave structure) may be substantially the same as in FIGS. 3 and 4, and therefore may not be provided. The structure as illustrated in FIG. 8 may be provided by removing a hard mask layer MHM through a method, such as wet etching, before providing the third via planarization layer VIA3.

FIG. 9 is an exemplary illustration of a portion of a cross-section of a display panel according to one or more embodiments of the present disclosure. A difference from the lamination structure as illustrated in FIG. 3 is that the ashing stopper layer ASST may be on the second source-drain electrode SD2 in FIG. 9. Hereinafter, a description of a concave structure (e.g., a substantially concave structure) may be substantially the same as in FIGS. 3 and 4, and therefore may not be provided.

FIG. 10 is a flow chart of a manufacturing method S10 of a display panel according to one or more embodiments of the present disclosure. Herein, a repeated description of the display panel as described in one or more embodiments may not be provided in a description of a manufacturing method S10 of a display panel.

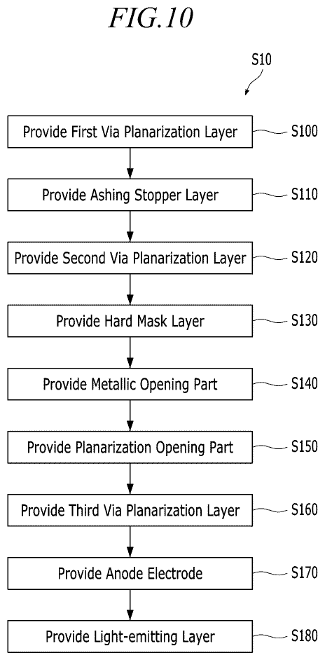

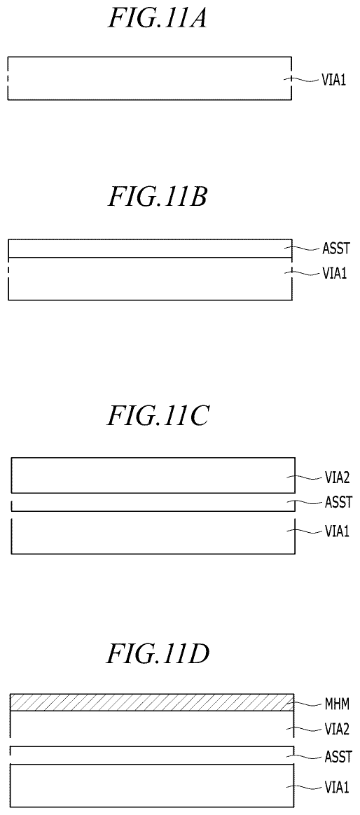

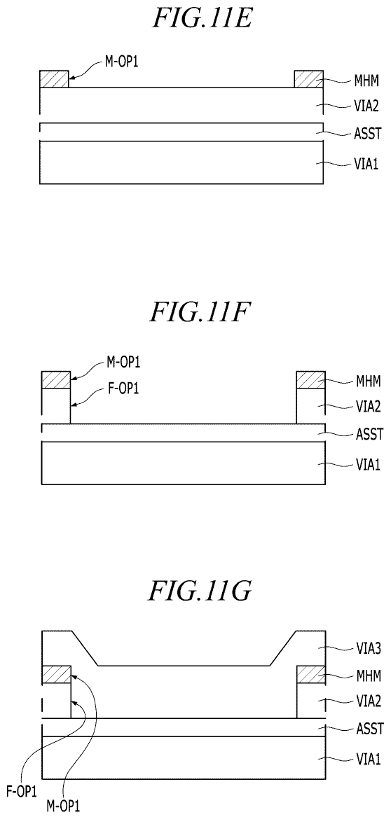

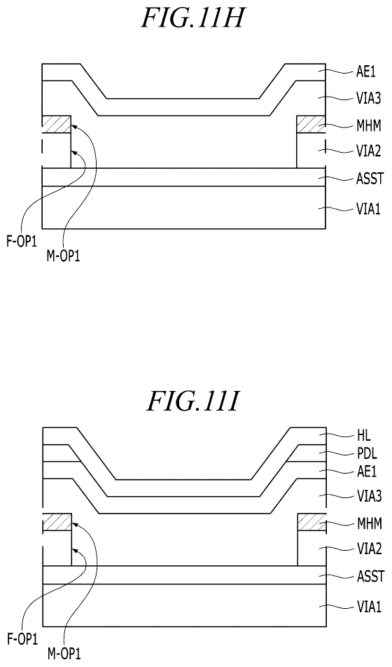

FIGS. 11A, 11B, 11C, 11D, 11E, 11F, 11G, 11H, 11I, and 11J are cross-sectional illustrations that correspond to a partial process of the manufacturing method S10 of a display panel according to one or more embodiments of the present disclosure. In the present disclosure, a manufacturing method S10 of a section marked with AA as illustrated in FIG. 3 is illustrated for convenience. In one or more embodiments, the manufacturing method S10 of a display panel may be substantially identically applied also to a region other than a section marked with AA as illustrated in FIG. 3.

Referring to FIGS. 10 and 11A, the manufacturing method S10 of a display panel according to one or more embodiments of the present disclosure may include a step of providing a first via planarization layer S100.

Referring to FIGS. 10 and 11B, the manufacturing method S10 of a display panel according to one or more embodiments of the present disclosure may include a step of providing an ashing stopper layer S110 by providing an ashing stopper layer ASST on the first via planarization layer VIA1 after the step of providing a first via planarization layer S100. In one or more embodiments, the ashing stopper layer ASST may include an inorganic material.

Referring to FIGS. 10 and 11C, a manufacturing method S10 of a display panel according to one or more embodiments of the present disclosure may include a step of providing a second via planarization layer S120 by providing a second via planarization layer VIA2 on the ashing stopper layer ASST after the step of providing an ashing stopper layer S110.

Referring to FIGS. 10 and 11D, the manufacturing method S10 of a display panel according to one or more embodiments of the present disclosure may include a step of providing a hard mask layer S130 by providing a hard mask layer MHM on the second via planarization layer VIA2 after the step of providing a second via planarization layer S120. In one or more embodiments, the hard mask layer MHM may include a metallic material.

Referring to FIGS. 10 and 11E, the manufacturing method S10 of a display panel according to one or more embodiments of the present disclosure may include a step of providing a metallic opening part S140 by providing a first metallic opening part M-OP1 on the hard mask layer MHM after the step of providing a hard mask layer S130. In the present disclosure, the step of providing a first metallic opening part M-OP1 may be performed by a photoresist process. The photoresist process may further include a step of providing a photoresist layer that entirely overlaps with the upper surface of the hard mask layer MHM. The step of providing a metallic opening part S140 may further include an etching process after the photoresist process.

Referring to FIGS. 10 and 11F, the manufacturing method S10 of a display panel according to one or more embodiments of the present disclosure may include a step of providing a planarization opening part S150 by providing a part F-OP1 on the second via planarization layer VIA2 after the step of providing a metallic opening part S140. The step of providing a first planarization opening part F-OP1 may be performed by a photoresist process. The photoresist process may further include a step of providing a photoresist layer that entirely overlaps with the upper surface of the hard mask layer MHM. The step of providing a planarization opening part S150 may further include an etching process after the photoresist process. In the step of providing a planarization opening part S150, the hard mask layer MHM may be used as a mask to provide planarization opening parts F-OP1, F-OP2, and F-OP3.

Referring to FIGS. 10 and 11G, the manufacturing method S10 of a display panel according to one or more embodiments of the present disclosure may include a step of providing a third via planarization layer S160 by providing a third via planarization layer VIA3 on the hard mask layer MHM after the step of providing a planarization opening part S150. According to one or more embodiments of the present disclosure, the third via planarization layer VIA3 may include a region that overlaps with the first metallic opening part M-OP1 and the first planarization opening part F-OP1. As the etching process is performed in the step of providing a metallic opening part S140 and the step of providing a planarization opening part S150, a region of the third via planarization layer VIA3 that overlaps with an etched portion of the second via planarization layer VIA2 may have a concave shape (e.g., a substantially concave shape).

According to one or more embodiments of the present disclosure, a step of removing the hard mask layer by removing the hard mask layer MHM may be further included between the step of providing a planarization opening part S150 and the step of providing a third via planarization layer S160. In one or more embodiments, the hard mask layer MHM may be removed by a wet etching process. If (e.g., when) the hard mask layer MHM is removed, the third via planarization layer VIA3 may be provided on the second via planarization layer VIA2 in the step of providing the third via planarization layer S160.

Referring to FIGS. 10 and 11H, the manufacturing method S10 of a display panel according to one or more embodiments of the present disclosure, a step of providing an anode electrode S170 by providing a first anode electrode AE1 on the third via planarization layer VIA3 may be included after the step of providing a third planarization layer S160. An upper surface of the third via planarization layer VIA3 may have a smooth surface (e.g., a substantially smooth surface) without deviation (e.g., substantial deviation) as a process, such as an etching, has not been performed on the third via planarization layer VIA3. In one or more embodiments, the first anode electrode AE1 may be stably (e.g., substantially stably) provided on the third via planarization layer VIA3 without a process deviation. In one or more embodiments, the anode electrode AE1 of a concave structure (e.g., a substantially concave structure) having relatively high quality and reliability may be provided.

According to one or more embodiments of the present disclosure, the first anode electrode AE1 may have a portion that overlaps with the first metallic opening part M-OP1 and the first planarization opening part F-OP1.

FIG. 11I is an illustration of a hole functional layer HL and a pixel defining film PDL added to FIG. 11H. In the present disclosure, a step of providing a hole functional layer HL and a pixel defining film PDL may not correspond to a characteristic aspect or feature of the present disclosure, and therefore is not separately described in the description of the manufacturing method S10 of a display panel.

Referring to FIGS. 10 and 11J, the manufacturing method S10 of a display panel according to one or more embodiments of the present disclosure may include a step of providing a light-emitting layer S180 by providing a first light-emitting layer EML1 on the hole functional layer HL after the step of providing an anode electrode S170. As described in one or more embodiments, the first anode electrode AE1 may have relatively high quality and reliability, and therefore the first light-emitting layer EML1 on the first anode electrode AE1 may also have relatively high quality and reliability.

According to one or more embodiments of the present disclosure, the first light-emitting layer EML1 may have a region that overlaps with the first metallic opening part M-OP1 and the first planarization opening part F-OP1.

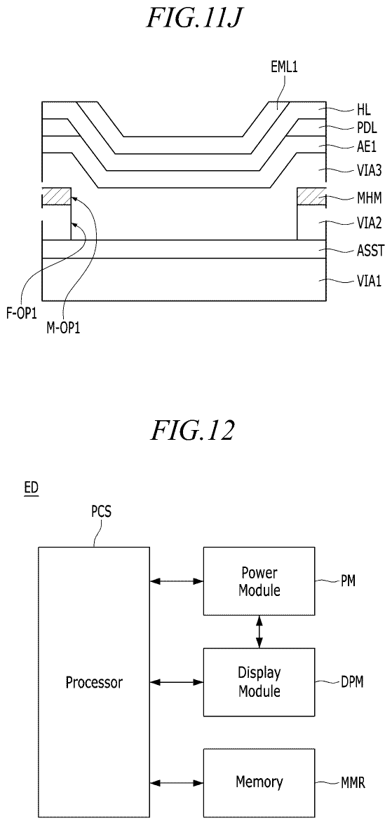

FIG. 12 is an exemplary block diagram of an electronic device according to one or more embodiments.

Referring to FIG. 12, the electronic device ED according to one or more embodiments may include a display module DPM, a processor PCS, a memory MMR, and a power module PM.

The processor PCS may include at least one selected from among a central processing unit CPU, an application processor AP, a graphic processing unit GPU, a communication processor CP, an image signal processor ISP, and a controller.

The memory MMR may be provided to store data information to operate the processor PCS or the display module DPM. If (e.g., when) the processor PCS operates an application stored in the memory MMR, the display module DPM may be provided to receive an image data signal and/or an input control signal and process the received signal to provide an output of image information through a display screen.

A power module PM may include a power supply module, such as a power adapter and/or a battery device, and a power conversion module, which converts power supplied by the power supply module to generate power to operate an electronic device ED.

At least one of the elements of the electronic device ED as described in one or more embodiments may be included in the display device according to one or more embodiments. In one or more embodiments, one or more of individual modules functionally included in a single module may be included in the display device, and the other may be provided separately from the display device. For example, a display module may be included in the display device, and the processor PCS, the memory MMR, and the power module PM may be provided in a form of another device within the electronic device ED other than the display device.

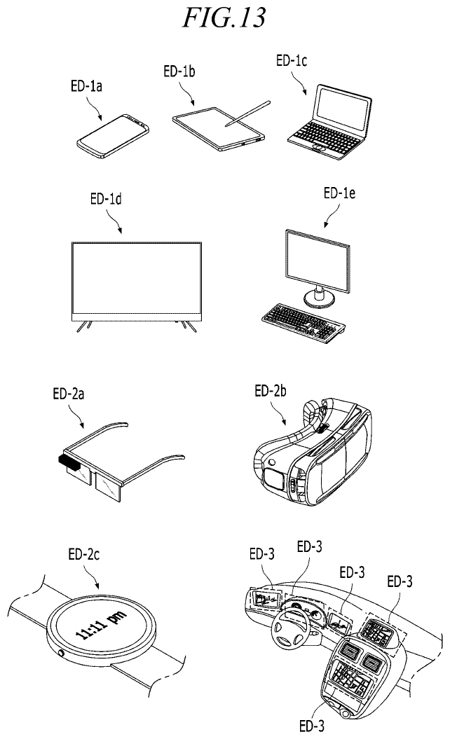

FIG. 13 illustrates schematic diagrams of electronic devices according to one or more embodiments.

Referring to FIG. 13, one or more suitable electronic devices having display devices according to one or more embodiments may include not only an image display electronic device, such as a smart phone ED-1a, a tablet PC ED-1b, a laptop ED-1c, a TV ED-1d, and a desk monitor ED-1e, but also a wearable electronic device including a display module, such as a smart glass ED-2a, a head mounted display ED-2b, and/or a smart watch ED-2c, and/or a vehicle electronic device ED-3 including a display module, such as a Center Information Display (CID) and/or a room mirror display on an instrument panel, center fascia, and/or a dashboard of an automobile.

While certain embodiments of the present disclosure have been described and illustrated herein, a person having ordinary skill in the art to which the present disclosure pertains shall appreciate that there may be one or more suitable modifications and permutations of the present disclosure without departing from the spirit and scope of the present disclosure that are defined in the appended claims and equivalents thereof. Moreover, it shall be appreciated that the disclosed embodiments are not intended to restrict the aspects and features of the present disclosure thereto and that the technical ideas and aspects of the present disclosure are interpreted to be included within the scope of the appended claims and their equivalents.

What is claimed is:

1. A display panel, comprising:
a base member;
an active pattern provided on the base member and comprising a semiconductor material;
a gate insulating layer that covers the active pattern;
a gate electrode provided on the gate insulating layer and having at least a portion that overlaps with the active pattern;
an interlayer insulating layer provided on the gate electrode;
a source-drain electrode provided on the interlayer insulating layer;
a first via planarization layer provided on the source-drain electrode;
an ashing stopper layer comprising an inorganic material and provided on the first via planarization layer;
a second via planarization layer provided on the ashing stopper layer and defined with a plurality of planarization opening parts;
a third via planarization layer provided on the second via planarization layer;
a plurality of anode electrodes provided on the third via planarization layer and having at least one overlapping with the plurality of planarization opening parts; and
a plurality of light-emitting layers, each provided on the plurality of anode electrodes.

2. The display panel as claimed in claim 1,
wherein the plurality of light-emitting layers comprise a first light-emitting layer that overlaps with any one of the plurality of planarization opening parts, and
wherein the first light-emitting layer comprises a first light-emitting unit that extends in a selectable direction and a second light-emitting unit that extends in a direction that crosses with the selectable direction.

3. The display panel as claimed in claim 2,
wherein an angle between a plane parallel to the first via planarization layer and the second light-emitting unit is 15 degrees or more and 25 degrees or less.

4. The display panel as claimed in claim 2,
wherein a distance between an upper surface of the first via planarization layer and the first light-emitting unit is less than a distance between the upper surface of the first via planarization layer and the second light-emitting unit.

5. The display panel as claimed in claim 2,
wherein a distance between a portion of an upper surface of the third via planarization layer that overlaps with the planarization opening part and an upper surface of the first via planarization layer is a first distance,
wherein a distance between a portion of the upper surface of the third via planarization layer that does not overlap with the planarization opening part and the upper surface of the first via planarization layer is a second distance, and
wherein the first distance is less than the second distance.

6. The display panel as claimed in claim 2,
wherein at least one of the plurality of anode electrodes comprises a first anode unit that extends in a selectable direction and a second anode unit that extends in a direction that crosses with the selectable direction.

7. The display panel as claimed in claim 2,
wherein the plurality of light-emitting layers further comprise a second light-emitting layer; and
wherein a distance between an upper surface of the first via planarization layer and a bottom surface of the first light-emitting layer is less than a distance between the upper surface of the first via planarization layer and a bottom surface of the second light-emitting layer.

8. The display device as claimed in claim 7,
wherein the first light-emitting layer emits light having a first wavelength, and
wherein the second light-emitting layer emits light having a second wavelength, which is shorter than the first wavelength.

9. The display panel as claimed in claim 2,
wherein a hard mask layer comprising a metallic material and defined with a plurality of metallic opening parts overlapping with the plurality of planarization opening parts is further comprised, and
wherein the hard mask layer is between the second via planarization layer and the third via planarization layer.

10. The display panel as claimed in claim 2,
wherein an angle between each of inner surfaces that defines the plurality of planarization opening parts and a normal line of the ashing stopper layer is an acute angle.

11. An electronic device comprising a display panel,
wherein the display panel comprises:
a base member;
an active pattern provided on the base member and comprising a semiconductor material;
a gate insulating layer that covers the active pattern;
a gate electrode provided on the gate insulating layer and having at least a portion that overlaps with the active pattern;
a source-drain electrode provided on the gate electrode;
a first via planarization layer provided on the source-drain electrode;
an ashing stopper layer comprising an inorganic material and provided on the first via planarization layer;
a second via planarization layer provided on the ashing stopper layer and defined with a plurality of planarization opening parts;
a third via planarization layer provided on the second via planarization layer;
a plurality of anode electrodes provided on the third via planarization layer and having at least one overlapping with the plurality of planarization opening parts; and
a plurality of light-emitting layers, each provided on the plurality of anode electrodes.

12. The electronic device as claimed in claim 11,
wherein the plurality of light-emitting layers comprise a first light-emitting layer that overlaps with any one of the plurality of planarization opening parts, and
wherein the first light-emitting layer comprises a first light-emitting unit that extends in a selectable direction and a second light-emitting unit that extends in a direction that crosses with the selectable direction.

13. The electronic device as claimed in claim 12,
wherein an angle between a plane parallel to the first via planarization layer and the second light-emitting unit is 15 degrees or more and 25 degrees or less.

14. The electronic device as claimed in claim 12,
wherein a distance between an upper surface of the first via planarization layer and the first light-emitting unit is less than a distance between the upper surface of the first via planarization layer and the second light-emitting unit.

15. The electronic device as claimed in claim 12,
wherein a distance between a portion of an upper surface of the third via planarization layer that overlaps with the planarization opening part and an upper surface of the first via planarization layer is a first distance,
wherein a distance between a portion of the upper surface of the third via planarization layer that does not overlap with the planarization opening part and the upper surface of the first via planarization layer is a second distance, and
wherein the first distance is less than the second distance.

16. The electronic device as claimed in claim 12,
wherein at least one of the plurality of anode electrodes comprises a first anode unit that extends in a selectable direction and a second anode unit that extends in a direction that crosses with the selectable direction.

17. The electronic device as claimed in claim 12,
wherein the plurality of light-emitting layers further comprise a second light-emitting layer, and
wherein a distance between an upper surface of the first via planarization layer and a bottom surface of the first light-emitting layer is less than a distance between the upper surface of the first via planarization layer and a bottom surface of the second light-emitting layer.

18. The electronic device as claimed in claim 17,
wherein the first light-emitting layer emits light having a first wavelength, and
wherein the second light-emitting layer emits light having a second wavelength, which is shorter than the first wavelength.

19. A method of manufacturing a display panel, comprising:
providing a first via planarization layer that covers an electrode pattern;
providing an ashing stopper layer on the first via-planarization layer, wherein the ashing stopper layer comprises an inorganic material;
providing a second via planarization layer on the ashing stopper layer;
providing a hard mask layer by providing a hard mask layer on the second via planarization layer, wherein the hard mask layer comprises a metallic material;
providing a metallic opening part by providing a metallic opening part on the hard mask layer;
providing a planarization opening part by providing a planarization opening part on the second via planarization layer, wherein the planarization opening part overlaps with the metallic opening part;
providing a third via planarization layer by providing a third via planarization layer on the second via planarization layer;
providing an anode electrode by providing an anode electrode on the third via planarization layer so that the anode electrode overlaps with the planarization opening part; and
providing a light-emitting layer by providing a light-emitting layer on the anode electrode.

20. The method as claimed in claim 19, further comprising:
removing the hard mask layer between the providing of the planarization opening part and the providing of the third via planarization layer.
